(19) United States
(12) Patent Application Publication
(10) Pub. No.: US 2023/0146027 A1
(43) Pub. Date: May 11, 2023

(54) QUANTUM DOT FILM, METHOD OF PREPARING THE SAME, AND DISPLAY DEVICE

(71) Applicant: TCL China Star Optoelectronics Technology Co., Ltd., Shenzhen, Guangdong (CN)

(72) Inventor: Zihang SONG, Shenzhen, Guangdong (CN)

(73) Assignee: TCL China Star Optoelectronics Technology Co., Ltd., Shenzhen, Guangdong (CN)

(21) Appl. No.: 17/049,052

(22) PCT Filed: Sep. 21, 2020
(86) PCT No.: PCT/CN2020/116381

§ 371 Date: Oct. 20, 2020

(30) Foreign Application Priority Data
Jul. 13, 2020 (CN) 202010669010.X

(51) Int. Cl. G02F 1/1335; G02F 1/13357; H10K 50/115; C09K 11/08; C09K 11/77; C08J 5/18

(52) U.S. Cl. CPC G02F 1/133614; G02F 1/133606; H10K 50/115; C09K 11/0811; C09K 11/77066; C09K 11/77067; C09K 11/77062; C09K 11/08; C08J 5/18; C08J 2383/04; C08J 2363/00; C08J 2333/26; C08J 2333/08

(57) ABSTRACT

A quantum dot film, a method of preparing the same, and a display device are disclosed. The quantum dot film includes a quantum dot layer and a plurality of protection layers. The quantum dot layer includes a plurality of red quantum dots, green quantum dots and scattering particles, which are uniformly dispersed in a high molecular polymer substrate. Material of the plurality of scattering particles is high refractive index material with a particle size ranging from 200 nm to 1 μm. By the plurality of scattering particles with a high refractive index disposed in the quantum dot layer, the self-absorption phenomenon between a plurality of quantum dots is reduced, and a light extraction rate is improved.

### FIELD OF INVENTION

The present application relates to the field of display technologies, and in particular to a quantum dot film, a method of preparing the same, and a display device.

### BACKGROUND OF INVENTION

Quantum dots (QDs) are a kind of semiconductor nanocrystal. The energy band structure of quantum dots can be changed by adjusting a size of quantum dots, and thus quantum dots can emit light of different wavelengths when excited by a light source. Accordingly, quantum dots, used as a kind of luminescent material with high luminous efficiency, high chromatographic purity, and adjustable luminescence wavelength, have received widespread attention. With the gradual maturity of quantum dot synthesis technology, applications of quantum dots have become extensive. For example, at present, quantum dots and resins are generally mixed to prepare quantum dot brightness enhancement films, which are applied to thin film transistor liquid crystal display devices (TFT-LCD), so as to greatly improve color gamut and color expression of liquid crystal displays. The color gamut of liquid crystal products with an NTSC of about 70% can be increased to more than 90%, or even more than 100%. However, due to multiple factors in the synthesis of quantum dots, the cost of quantum dots is high. In addition, due to the requirement of luminous intensity, a concentration of quantum dots in a quantum dot enhancement film is high, and spacing between the quantum dots is small. Thus, the excited light of the quantum dots may be absorbed by other quantum dots, i.e., a phenomenon of quantum dot self-absorption, so that the excited light cannot be emitted, resulting in waste of energy, which hinders the application of quantum dots in products.

Therefore, the existing quantum dot film has the problem of quantum dot self-absorption that needs to be solved.

### SUMMARY OF INVENTION

The present application provides a quantum dot film, a method of preparing the same, and a display device, so as to alleviate a technical problem of the self-absorption phenomenon between a plurality of quantum dots in the existing quantum dot film.

In order to solve the above problems, the technical solutions provided by the present application are as follows.

An embodiment of the present application provides a quantum dot film, comprising: a quantum dot layer, and the quantum dot layer including: a plurality of quantum dots; and a plurality of scattering particles dispersed between the plurality of quantum dots. A particle size of each of the plurality of scattering particles ranges from 200 nanometers to 1 micrometer.

In the quantum dot film provided in the embodiment of the present application, material of the plurality of scattering particles includes titanium dioxide or zirconium dioxide.

In the quantum dot film provided in the embodiment of the present application, the plurality of quantum dots include red quantum dots and green quantum dots.

In the quantum dot film provided in the embodiment of the present application, a particle size of each of the red quantum dots is more than a particle size of each of the green quantum dots.

In the quantum dot film provided in the embodiment of the present application, the quantum dot layer further includes a high molecular polymer substrate, and the plurality of quantum dots and the plurality of scattering particles are dispersed in the high molecular polymer substrate.

In the quantum dot film provided in the embodiment of the present application, high molecular polymer in the high molecular polymer substrate includes one or more of organic silicone resin, epoxy resin, polyacrylamide, acrylic resin, light curable resin, and thermal curable resin.

In the quantum dot film provided in the embodiment of the present application, the quantum dot film further comprises a pair of protection layers which are disposed on an upper surface and a lower surface of the quantum dot layer, respectively.

In the quantum dot film provided in the embodiment of the present application, material of the pair of protection layers includes at least one of aluminum nitride, aluminum oxynitride, titanium nitride, titanium oxynitride, zirconium nitride, zirconium oxynitride, silicon oxide, silicon nitride, silicon oxynitride, and graphene.

The embodiment of the application provides a method of preparing a quantum dot film, comprising: a step S10 of preparing a quantum dot layer, including dispersing a plurality of quantum dots and a plurality of scattering particles in a solution of high molecular polymer to form a quantum dot gel solution, and curing the quantum dot gel solution to form the quantum dot layer; and a step S20 of preparing a pair of protection layers, including depositing a pair of inorganic thin films as the protection layers on the upper surface and the lower surface of the quantum dot layer, respectively.

In the method of preparing the quantum dot film provided in the embodiment of the present application, the plurality of quantum dots include red quantum dots and green quantum dots.

In the method of preparing the quantum dot film provided in the embodiment of the present application, a particle size of each of the plurality of scattering particles ranges from 200 nanometers to 1 micrometer.

In the method of preparing the quantum dot film provided in the embodiment of the present application, material of the plurality of scattering particles includes titanium dioxide or zirconium dioxide.

In the method of preparing the quantum dot film provided in the embodiment of the present application, the high molecular polymer includes one or more of organic silicone resin, epoxy resin, polyacrylamide, acrylic resin, light curable resin, and thermal curable resin.

In the method of preparing the quantum dot film provided in the embodiment of the present application, the quantum dot gel solution is cured by at least one curing method of ultraviolet light irradiation, heating, solvent evaporation, or addition of a curing agent.

The embodiment of the application further provides a display device, comprising: a quantum dot film including a quantum dot layer and a pair of protection layers disposed on an upper surface and a lower surface of the quantum dot layer, respectively, wherein the quantum dot layer includes: a plurality of quantum dots; and a plurality of scattering particles dispersed between the plurality of quantum dots. A particle size of each of the plurality of scattering particles ranges from 200 nanometers to 1 micrometer.

In the display device provided in the embodiment of the present application, the plurality of quantum dots include red quantum dots and green quantum dots.

In the display device provided in the embodiment of the present application, a particle size of each of the red quantum dots is more than a particle size of each of the green quantum dots.

In the display device provided in the embodiment of the present application, material of the plurality of scattering particles includes titanium dioxide or zirconium dioxide.

In the display device provided in the embodiment of the present application, the display device further comprises a backlight module, a liquid crystal display panel disposed on the backlight module, an upper polarizer attached to an upper surface of the liquid crystal display panel, and a lower polarizer attached to a lower surface of the liquid crystal display panel.

In the display device provided in the embodiment of the present application, the backlight module includes a reflection sheet and a light guide plate disposed on the reflection sheet, wherein the quantum dot film is disposed on the light guide plate.

### BENEFICIAL EFFECT OF THE PRESENT APPLICATION

In the quantum dot film, the method of preparing the same, and the display device provided by the present application, the scattering particles with a high refractive index and a particle size of about 200 nanometers to 1 micrometer are added to the quantum dot layer. The scattering particles can expand a mutual distance between the quantum dots, thereby reducing the self-absorption phenomenon between the quantum dots, and improving the light extraction rate. Moreover, due to the presence of the scattering particles with a high refractive index, blue light will be scattered when passing through the scattering particles, thereby increasing an optical path of the blue light in a quantum dot brightness enhancement film, increasing a utilization rate of the blue light, improving a light efficiency of the quantum dots, and reducing the amount of the quantum dots and costs. In addition, the blue light is scattered due to the scattering effect of the scattering particles, thereby increasing an angle of the blue light exiting from the quantum dot brightness enhancement film, increasing the form the blue light, reducing a difference between the forms of red, green and blue lights, and reducing color shift.

### DESCRIPTION OF DRAWINGS

In order to more clearly illustrate the technical solution in the embodiment of the present application, the drawings necessary in the description of the embodiment will be introduced briefly below. Obviously, the drawings in the following description are only some embodiments of the present application, and for those ordinary skilled in the art, other drawings can be further obtained based on these drawings without creative works.

FIG. 1 is a side view of the structure of a quantum dot film provided by an embodiment of the present application.

FIG. 2 is a schematic structural diagram of the quantum dot film changing an optical path provided by an embodiment of the present application.

FIG. 3 is a schematic flowchart of a method of preparing a quantum dot film provided by an embodiment of the present application.

FIG. 4 is a schematic side view of the structure of a liquid crystal display device provided by an embodiment of the present application.

FIG. 5 is a schematic side view of the structure of an OLED display device provided by an embodiment of the present application.

### DETAILED DESCRIPTION OF PREFERRED EMBODIMENTS

The following embodiments refer to the accompanying drawings for exemplifying specific implementable embodiments of the present application. Furthermore, directional terms described by the present application, such as upper, lower, front, back, left, right, inner, outer, side and etc., are only directions by referring to the accompanying drawings, and thus the used directional terms are used to describe and understand the present application, but the present invention is not limited thereto. Like reference numerals designate like elements throughout the specification

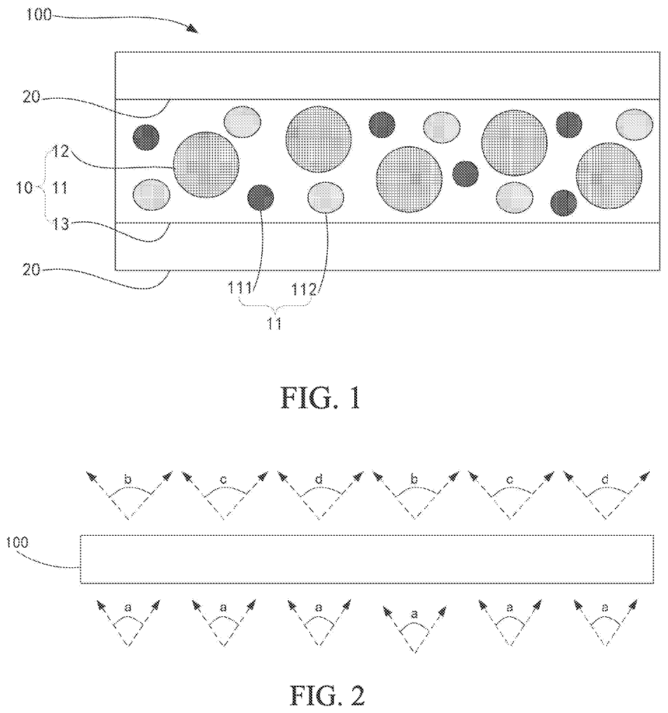

In one embodiment, a quantum dot film 100 is provided. As shown in FIG. 1, the quantum dot film 100 includes a quantum dot layer 10 and a pair of protection layers 20 disposed on an upper surface and a lower surface of the quantum dot layer 10, respectively. The quantum dot layer 10 includes a high molecular polymer substrate 13, and further includes quantum dots 11 and scattering particles 12 uniformly dispersed in the high molecular polymer substrate 13.

Specifically, each of the quantum dot 11 is a core-shell structure composed of semiconductor materials, including a quantum dot central core and an outer shell. Material of the quantum dots includes one or more of MgS, CdTe, CdSe, CdS, CdZnS, ZnSe, ZnTe, ZnS, ZnO, GaAs, GaN, GaP, InP, InAs, InN, InSb, AlP, AlSb, etc. For example, the central core is a CdSe core, and the outer shell is a ZnS shell. A particle size of the quantum dot 11 is generally about 10 nanometers. Due to a difference in a size of the quantum dots, a wavelength of the emitted light of the quantum dots 11 varies with the particle size and composition.

Further, the quantum dots 11 includes red quantum dots 112 and green quantum dots 111. A particle size of the green quantum dots 111 is smaller than a particle size of the red quantum dots 112. The red quantum dots 112 are excited by light to emit red light, and the green quantum dots 111 are excited by light to emit green light. The excitation light used in the present application includes blue light, and a blue LED can be used as the excitation light source. Red light, green light, and blue light are mixed to produce white light and exit from the quantum dot layer.

It should be noted that the quantum dots 11 can convert the absorbed light with a short wavelength into the light with a long wavelength. In order to obtain a quantum dot film with a predetermined color, the quantum dots in the quantum layer may include one or more types. In the present application, the quantum dots include not only the quantum dots limited to emit red and green light, but also the quantum dots that emit any wavelength within the visible wavelength range.

Further, the scattering particles 12 with a particle size ranging from 200 nanometers to 1 micrometer and the quantum dots 11 are mixed together in the high molecular polymer solution, and are cured to form the quantum dot layer 10. The scattering particles 12 can expand the mutual distance between the quantum dots 11, thereby reducing the self-absorption phenomenon between the quantum dots 11, and improving the light extraction rate.

Further, material of the scattering particles 12 includes inorganic semiconductor materials with a high refractive index, such as titanium dioxide and zirconium dioxide. Materials with different refractive indexes have different light scattering intensity. The greater the refractive index, the greater the scattering intensity. When the excitation light irradiates the scattering particles with a high refractive index, the excitation light will be scattered by the scattering particles, and the scattered light can excite the quantum dots again, thereby increasing the optical path of the excitation light in the quantum dot brightness enhancement film, improving the utilization rate of the blue light, improving the light efficiency of the quantum dots, and reducing the amount of the quantum dots and the costs.

Further, the high molecular polymer substrate 13 is formed after the high molecular polymer solution is cured. The high molecular polymer solution is formed by doping high molecular polymer in an organic solvent. The high molecular polymer includes one or more of high molecular materials, such as silicone resin, epoxy resin, polyacrylamide, acrylic resin, light curable resin, and thermal curable resin. For example, the high molecular polymer substrate may be polyethylene terephthalate (PET), triacetate cellulose (TAC), or the like.

Further, the pair of protection layers 20 are respectively deposited on the upper surface and the lower surface of the quantum dot layer 10 to form the quantum dot film 100, wherein the protection layers 20 are used to prevent water and oxygen from entering the quantum dot layer 10. Material of the protection layers 20 may be inorganic material with strong water and oxygen barrier. A dense arrangement of the inorganic material at the atomic level can effectively block moisture and oxygen. The inorganic material includes at least one of aluminum nitride, aluminum oxynitride, titanium nitride, titanium oxynitride, zirconium nitride, zirconium oxynitride, silicon oxide, silicon nitride, silicon oxynitride, graphene, and the like.

It should be noted that the upper surface of the quantum dot layer 10 refers to a light-emitting surface of the quantum dot layer 10, and the lower surface of the quantum dot layer 10 refers to a light incident surface of the quantum dot layer 10, i.e., a side illuminated by an excitation light source.

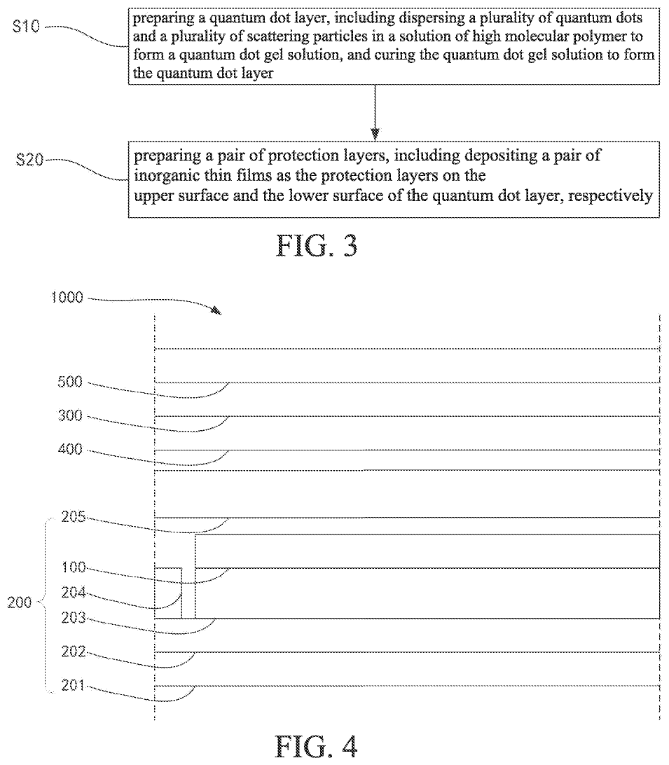

Further, as shown in FIG. 2, the blue light emitted by the blue LED enters the quantum dot film 100 at a certain viewing angle a. The red quantum dots in the quantum dot film are excited by the blue light to emit red light, and the red light exits from the light-emitting surface of the quantum dot film at a certain viewing angle b. The green quantum dots in the quantum dot film are excited by the blue light to emit green light, and the green light is also emitted from the light-emitting surface of the quantum dot film at a certain viewing angle c. In addition, the blue light, which is scattered due to scattering effect of the scattering particles in the quantum dot film, is emitted from the light-emitting surface of the quantum dot layer at a certain viewing angle d. The viewing angle b is greater than the viewing angle a, the viewing angle c is greater than the viewing angle a, and the viewing angle d is greater than viewing angle a. Due to the presence of the scattering particles with a high refractive index, the exit angle of the blue light after passing through the quantum dot film is greater than the incident angle, thereby increasing an angle of the blue light exiting from the quantum dot brightness enhancement film, increasing the form of blue light, reducing a difference between the forms of red, green and blue lights, and reducing color shift.

In an embodiment, as shown in FIG. 3, a method of preparing a quantum dot film is provided, including the following steps.

A step S10 of preparing a quantum dot layer, including dispersing a plurality of quantum dots and a plurality of scattering particles in a solution of high molecular polymer to form a quantum dot gel solution, and curing the quantum dot gel solution form a quantum dot layer.

Specifically, the plurality of quantum dots include red quantum dots and green quantum dots. The scattering particles include inorganic semiconductor material with a high refractive index and with a particle size ranging from 200 nanometers to 1 millimeter, such as titanium dioxide and zirconium dioxide.

Further, the quantum dots and the scattering particles are mixed in the solution of high molecular polymer to form a quantum dot gel solution.

Specifically, the solution of high molecular polymer is formed by doping high molecular polymer in an organic solvent. The high molecular polymer includes one or more of high molecular materials such as silicone resin, epoxy resin, polyacrylamide, acrylic resin, light curable resin, and thermal curable resin.

Further, the quantum dot gel solution is cured to form a quantum dot film. Specifically, the quantum dot gel solution can be cured by ultraviolet light irradiation, heating, solvent evaporation, or addition of a curing agent. For example, when the solution of high molecular polymer is epoxy resin, the quantum dot gel solution is generally cured by adding acid anhydride curing agents, acid curing agents, or amine curing agents. When the solution of high molecular polymer is acrylic resin, the quantum dot gel solution is generally cured by ultraviolet light irradiation or heating.

It is understandable that an auxiliary substrate is needed under curing the quantum dot gel solution. The mixed quantum dot gel solution is spread on the auxiliary substrate by coating or the like, and then is cured to form a film. Finally, the auxiliary substrate is peeled off to prepare the required quantum dot layer. The auxiliary substrate may be an easily peelable release film substrate, for example, a PET release film, a PC release film, and the like.

A step S20 of preparing a pair of protection layers, including depositing a pair of inorganic thin films as the protection layers on the upper surface and the lower surface of the quantum dot layer, respectively.

Specifically, chemical vapor deposition, plasma enhance chemical vapor deposition, atomic layer deposition, and other deposition processes are used to deposit a pair of inorganic thin films as the protection layers on the upper surface and the lower surface of the quantum dot layer, respectively.

Specifically, material of the inorganic thin film includes at least one of aluminum nitride, aluminum oxynitride, titanium nitride, titanium oxynitride, zirconium nitride, zirconium oxynitride, silicon oxide, silicon nitride, silicon oxynitride, graphene, and the like. The inorganic thin film can effectively prevent moisture and oxygen from entering the quantum dot layer.

In an embodiment, a liquid crystal display device 1000 is provided. As shown in FIG. 4, the liquid crystal display device 1000 includes a backlight module 200, a liquid crystal display panel 300 on the backlight module 200, a lower polarizer 400 attached to a lower surface of the liquid crystal display panel 300 between the module 200 and the liquid crystal display panel 300, and an upper polarizer 500 attached to a upper surface of the liquid crystal display panel 300.

Specifically, the backlight module 200 includes a back plate 201, a reflection sheet 202, a light guide plate 203, a light source 204, an optical film 205, and the quantum dot film 100 of one of the foregoing embodiments. The back plate 201 is formed with a receiving chamber. The receiving chamber is used for accommodating the reflection sheet 202, the light guide plate 203, the light source 204, the optical film 205, and the quantum dot film 100. The light source 204 includes a blue LED or the like, and the light source 204 is disposed on one side of the light guide plate 203. The quantum dot film 100 is disposed on the light guide plate 203, i.e., on a light-emitting surface of the light guide plate 203. The optical film 205 is disposed on the quantum dot film 100. The reflection sheet 102 is disposed on a lower surface of the light guide plate 203.

Specifically, the blue light emitted by the blue LED is directed to the light guide plate 203, and is emitted from the light-emitting surface of the light guide plate 203 through reflection, refraction and the like. The light emitted from the light guide plate 203 passes through the quantum dot film 100. The red quantum dots in the quantum dot film 100 are excited by the blue light to emit red light, and the green quantum dots are excited by the blue light to emit green light. The red light, the green light, and the blue light are mixed to produce white light to emit from the light-emitting surface of the quantum dot film 100.

Further, when the blue light emitted from the light guide plate 203 irradiates scattering particles with a high refractive index in the quantum dot film 100, the blue light will be scattered by the scattering particles, and the scattered light can excite the quantum dots again, thereby increasing an optical path of the blue light in the quantum dot film, increasing a utilization rate of the blue light, improving a light efficiency of the quantum dots, and reducing the amount of the quantum dots and costs. In addition, the blue light, which is scattered due to scattering effect of the scattering particles in the quantum dot layer, is emitted from the light-emitting surface of the quantum dot layer at a certain viewing angle, thereby increasing an angle of the blue light exiting from a quantum dot brightness enhancement film, increasing the form of blue light, reducing a difference between the forms of red, green and blue lights, and reducing color shift of the liquid crystal display panel.

It should be noted that the backlight module 200 may also adopt a direct type backlight, and the quantum dot film 100 is not limited to be disposed on the light guide plate 203. The quantum dot film may also be disposed opposite to the light source, or attached to the lower polarizer, etc.

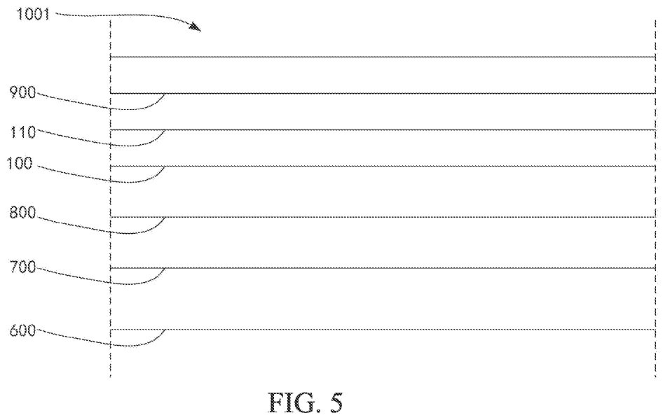

In another embodiment, an OLED display device 1001 is provided. As shown in FIG. 5, the OLED display device 1001 includes a substrate 600, a driving circuit layer 700, a light-emitting function layer 800, an encapsulation layer 900, a color filter 110, and the quantum dot film 100 of one of the foregoing embodiments. The driving circuit layer 700 is disposed on the substrate 600. The light-emitting function layer 800 is disposed on the driving circuit layer 700, and luminescent material of the light-emitting function layer 800 is blue luminescent material for emitting blue light. The quantum dot film 100 is disposed on the light-emitting function layer 800. The color filter 110 is disposed on the quantum dot film 100. The encapsulation layer 900 is disposed on the color filter 110.

Specifically, when the blue light emitted by the light-emitting function layer passes through the quantum dot film, the red quantum dots in the quantum dot film are excited by the blue light to emit red light, and the green quantum dots are excited by the blue light to emit green light. The red light, the green light, and the blue light are mixed to produce white light to emit from the light-emitting surface of the quantum dot film. The white light emitted from the light-emitting surface of the quantum dot film passes through the color filter to present various colors.

According to the above embodiments, it can be seen that:

The present application provides the quantum dot film, the method of preparing the same, and the display device. The quantum dot film includes the quantum dot layer and a pair of protection layer deposited on the upper surface and the lower surface of the quantum dot layer. The quantum dot layer includes red quantum dots, green quantum dots and scattering particles uniformly dispersed in the high molecular polymer substrate. The scattering particles are inorganic semiconductor materials with a high refractive index and a particle size ranging from 200 nm to 1 mm. The scattering particles can expand a mutual distance between the quantum dots, thereby reducing the self-absorption phenomenon between the quantum dots, and improving the light extraction rate. Moreover, due to the presence of the scattering particles with a high refractive index, blue light will be scattered when passing through the scattering particles, thereby increasing an optical path of the blue light in a quantum dot brightness enhancement film, increasing a utilization rate of the blue light, improving a light efficiency of the quantum dots, and reducing the amount of the quantum dots and costs. In addition, the form of the blue light is scattered due to scattering effect of the scattering particles, thereby increasing an angle of the blue light exiting from the quantum dot brightness enhancement film, increasing the form of blue light, reducing a difference between the forms of red, green and blue lights, and reducing color shift.

In summary, although the present application has been disclosed as above with preferred embodiments, the above-mentioned preferred embodiments are not intended to limit the present application. Those of ordinary skill in the art can make various changes and modifications without departing from the spirit and scope of the present application. Therefore, the protection scope of the present application is subject to the scope defined by the claims.

What is claimed is:

1. A quantum dot film, comprising: a quantum dot layer, and the quantum dot layer including:
a plurality of quantum dots; and
a plurality of scattering particles dispersed between the plurality of quantum dots;
wherein a particle size of each of the plurality of scattering particles ranges from 200 nanometers to 1 micrometer.

2. The quantum dot film of claim 1, wherein material of the plurality of scattering particles includes titanium dioxide or zirconium dioxide.

3. The quantum dot film of claim 1, wherein the plurality of quantum dots include red quantum dots and green quantum dots.

4. The quantum dot film of claim 3, wherein a particle size of each of the red quantum dots is more than a particle size of each of the green quantum dots.

5. The quantum dot film of claim 1, wherein the quantum dot layer further includes a high molecular polymer substrate, and the plurality of quantum dots and the plurality of scattering particles are dispersed in the high molecular polymer substrate.

6. The quantum dot film of claim 5, wherein high molecular polymer in the high molecular polymer substrate includes one or more of organic silicone resin, epoxy resin, polyacrylamide, acrylic resin, light curable resin, and thermal curable resin.

7. The quantum dot film of claim 1, wherein the quantum dot film further comprises a pair of protection layers which are disposed on an upper surface and a lower surface of the quantum dot layer, respectively.

8. The quantum dot film of claim 7, wherein material of the pair of protection layers includes at least one of aluminum nitride, aluminum oxynitride, titanium nitride, titanium oxynitride, zirconium nitride, zirconium oxynitride, silicon oxide, silicon nitride, silicon oxynitride, and graphene.

9. A method of preparing a quantum dot film, comprising:
a step S10 of preparing a quantum dot layer, including dispersing a plurality of quantum dots and a plurality of scattering particles in a solution of high molecular polymer to form a quantum dot gel solution, and curing the quantum dot gel solution to form the quantum dot layer; and
a step S20 of preparing a pair of protection layers, including depositing a pair of inorganic thin films as the protection layers on the upper surface and the lower surface of the quantum dot layer, respectively.

10. The method of preparing the quantum dot film of claim 9, wherein the plurality of quantum dots include red quantum dots and green quantum dots.

11. The method of preparing the quantum dot film of claim 9, wherein a particle size of each of the plurality of scattering particles ranges from 200 nanometers to 1 micrometer.

12. The method of preparing the quantum dot film of claim 9, wherein material of the plurality of scattering particles includes titanium dioxide or zirconium dioxide.

13. The method of preparing the quantum dot film of claim 9, wherein the high molecular polymer includes one or more of organic silicone resin, epoxy resin, polyacrylamide, acrylic resin, light curable resin, and thermal curable resin.

14. The method of preparing the quantum dot film of claim 9, wherein the quantum dot gel solution is cured by at least one curing method of ultraviolet light irradiation, heating, solvent evaporation, or addition of a curing agent.

15. A display device, comprising: a quantum dot film including a quantum dot layer and a pair of protection layers disposed on an upper surface and a lower surface of the quantum dot layer, respectively, wherein the quantum dot layer includes:
a plurality of quantum dots; and
a plurality of scattering particles dispersed between the plurality of quantum dots;
wherein a particle size of each of the plurality of scattering particles ranges from 200 nanometers to 1 micrometer.

16. The display device of claim 15, wherein the plurality of quantum dots include red quantum dots and green quantum dots.

17. The display device of claim 16, wherein a particle size of each of the red quantum dots is more than a particle size of each of the green quantum dots.

18. The display device of claim 15, wherein material of the plurality of scattering particles includes titanium dioxide or zirconium dioxide.

19. The display device of claim 15, wherein the display device further comprises a backlight module, a liquid crystal display panel disposed on the backlight module, an upper polarizer attached to an upper surface of the liquid crystal display panel, and a lower polarizer attached to a lower surface of the liquid crystal display panel.

20. The display device of claim 19, wherein the backlight module includes a reflection sheet and a light guide plate disposed on the reflection sheet, wherein the quantum dot film is disposed on the light guide plate.
